(19) United States
(12) Patent Application Publication
(10) Pub. No.: US 2004/0240188 A1
(43) Pub. Date: Dec. 2, 2004

(54) Protective coating for attach hardware for circuits

(76) Inventors: Stephen Daniel Cromwell, Penryn, CA (US); Xiang Dai, Roseville, CA (US); Hamid R. Nikzad, Los Altos, CA (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/447,542

(22) Filed: May 28, 2003

(51) Int. Cl. H05K 1/18

(52) U.S. Cl. 361/761

(57) ABSTRACT

A component of an attach hardware assembly is configured for use in securing an Application Specific Integrated Circuit (ASIC) to a circuit board as part of the attach hardware assembly and has a protective coating to protect that component from corrosion.

### BACKGROUND

An Application-Specific Integrated Circuit (ASIC) is a microchip designed for a special application. The ASIC is designed to process information or complete tasks in a manner specific to the intended application. For example, ASICs are used in such diverse applications as auto emission control, environmental monitoring, and personal digital assistants (PDAs). ASICs are contrasted with general integrated circuits that can be used to perform different tasks for different applications. Examples of general integrated circuits include the microprocessor and the random access memory chips in a typical personal computer.

An ASIC can be mass produced for a special application or can be custom manufactured for a particular customer application. Custom production is typically performed using components from a “building block” library of ASIC components. Each ASIC includes a number of input/output (I/O) leads that allow the ASIC to be connected to a larger circuit and receive the signals and data with which the ASIC works. The ASIC is then usually attached to a circuit board, such as a printed circuit board (PCB). Leads or a socket on the circuit board make contact with the I/O leads of the ASIC and connect the ASIC to the larger circuit of which it is a part.

The ever growing I/O count in today's large ASICs requires a very high clamping load to secure the ASIC to the circuit board and ensure continuous electrical contact between the ASIC and the circuit on the PCB. Clamping loads in the range of 400 to 700 pounds are becoming common. As noted, a socket may be provided on the PCB into which the ASIC is clamped.

The result of such a high clamping load is high stress on certain components in the hardware used to attach the ASIC to the circuit board. This hardware is frequently referred to as the “attach hardware.” One such component of the attach hardware is the load plate. The load plate is a rigid plate that is typically made of steel and is sometimes referred to as a spring plate. The load pate is secured, typically with a screw or coil springs, to clamp the ASIC to the circuit board.

Once the ASIC is secured to the circuit board and placed in service, the environmental conditions to which the attach hardware is exposed typically tend to cause corrosion of the attach hardware. The high stresses experienced by the attach hardware can greatly accelerate this corrosion. Corrosion causes pitting, the pitting results in stress risers that lead to crack formation and eventual failure of the hardware. If the corrosion could be stopped or slowed, the failure of the attach hardware could be prevented or delayed and the useful life of the unit would be significantly increased.

To reduce the risk of stress-induced corrosion and cracking in the attach hardware, a few alternatives have been tried. For example, using multiple load plates reduces the stress on any one of the plates in the assembly. However, the use of multiple load plates results in increased cost and a higher spring rate. The higher spring rate can prevent the application of reasonable load tolerances. In another example, four springs are used at the corners of the load plate to more evenly distribute the load. However, the conventional four-corner coil spring design requires more parts and a time-consuming attach process. In addition, the springs block airflow needed for cooling the ASIC.

Reducing the load would also solve the problems related to high stress in the load plate and other attach hardware, but reducing the load would also greatly reduce the reliability of the electrical connection between the ASIC and the circuit on the circuit board for current socket technologies. The industry is presently developing sockets that require less of a load for a reliable connection. However such efforts have not yet succeeded and have failed to produce a reliable socket that does not require the high loads which lead to corrosion and failure of the attach hardware.

### SUMMARY

A component of an attach hardware assembly is configured for use in securing an Application Specific Integrated Circuit (ASIC) to a circuit board as part of the attach hardware assembly and has a protective coating to protect that component from corrosion.

### BRIEF DESCRIPTION OF THE DRAWINGS

The accompanying drawings illustrate various embodiments of the present invention and are a part of the specification. The illustrated embodiments are merely examples of the present invention and do not limit the scope of the invention.

FIG. 1 is an exploded view of an ASIC assembly including attach hardware protected from corrosion according to an embodiment of the present invention.

FIG. 2 is an illustration of the corrosion that typically occurs in the attach hardware of an ASIC assembly.

FIG. 3 is an illustration of attach hardware in an ASIC assembly that was treated according to an embodiment of the present invention and resisted corrosion under testing.

FIG. 4 is a flowchart illustrating a method of protecting attach hardware from corrosion according to another embodiment of the present invention.

Throughout the drawings, identical reference numbers designate similar, but not necessarily identical, elements.

### DETAILED DESCRIPTION

The present specification describes a method and system of coating components of attach hardware in an ASIC assembly with a coating that will prevent corrosion and, thereby, increase the reliability and useful life of the assembly. One example of such a protective coating is Xylan®, a fluoropolymer coating from the Whitford Corporation of Pennsylvania.

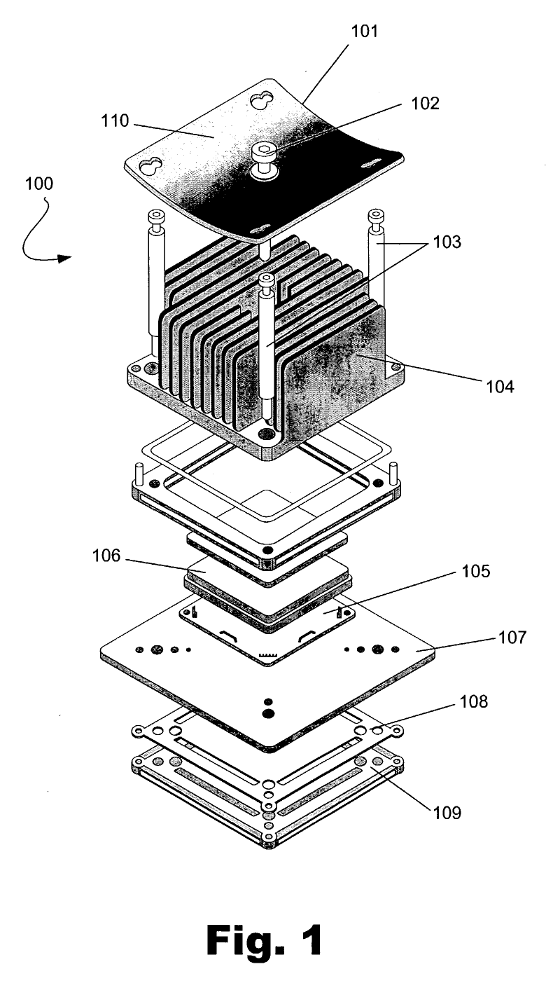

FIG. 1 illustrates an ASIC assembly (100) with attach hardware that has been made corrosion-resistant according to the principles described herein. As shown in FIG. 1, a typical ASIC assembly includes an ASIC (106) that is electrically connected to a circuit board (107), for example a printed circuit board. Typically, the ASIC (106) is connected to the circuit board (107) using a socket (105). An insulator (108) is disposed below the circuit board (107) to insulate the circuit board (107) from the attach hardware assembly which will be described below.

A heat sink (104) is typically included in the assembly to dissipate heat generated by the ASIC (106). An ASIC (106) will generate heat as it operates and, if this heat is not dissipated, can cause damage to the ASIC (106) or other components of the assembly (100).

As described above, the ASIC (106) and circuit board (107) are held together with an assembly of attach hardware. The attach hardware includes a load plate (101) and a bolster plate (109). Load studs (103) are also part of the attach hardware and run between the load plate (101) and the bolster plate (109).

The last component of the attach hardware is a load screw (102). The load screw (102) is tightened to secure the load plate (101) to the bolter plate (109) and to apply the desired load to the ASIC assembly components sandwiched between the load plate (101) and the bolster plate (109).

As shown in FIG. 1, the heat sink (104), ASIC (106), socket (105), circuit board (107) and insulator (108) are all sandwiched between the load plate (101) and the bolster plate (109) to complete the ASIC assembly (100).

Under the principles described herein, to protect the attach hardware from corrosion, a corrosion resistant coating is applied to one or more components of the attach hardware. In FIG. 1, a protective coating (110) is applied over the surface of the load plate (101). However, it will be understood that the protective coating can be applied to any or all of the components of the attach hardware assembly, e.g., the load plate (101), the bolster plate (109), the load screw (102) and the load studs (103).

It is, perhaps, most advantageous to apply to the protective coating (110) to the load plate (101) for the following reasons. The load plate (101) has a relatively large surface area that is exposed to high stress when the attach hardware assembly is in place. This large surface area under stress is particularly vulnerable to corrosion and will benefit significantly from the application of a corrosion-resistant coating (110).

The corrosion-resistant coating (110) can be any coating that will resist or prevent the corrosion of the attach hardware components in the operating environment of the ASIC assembly (100). As indicated above, an ASIC assembly may be used in a wide variety of different applications and operating environments. Consequently, different protective coatings may be preferred for different application of an ASIC assembly.

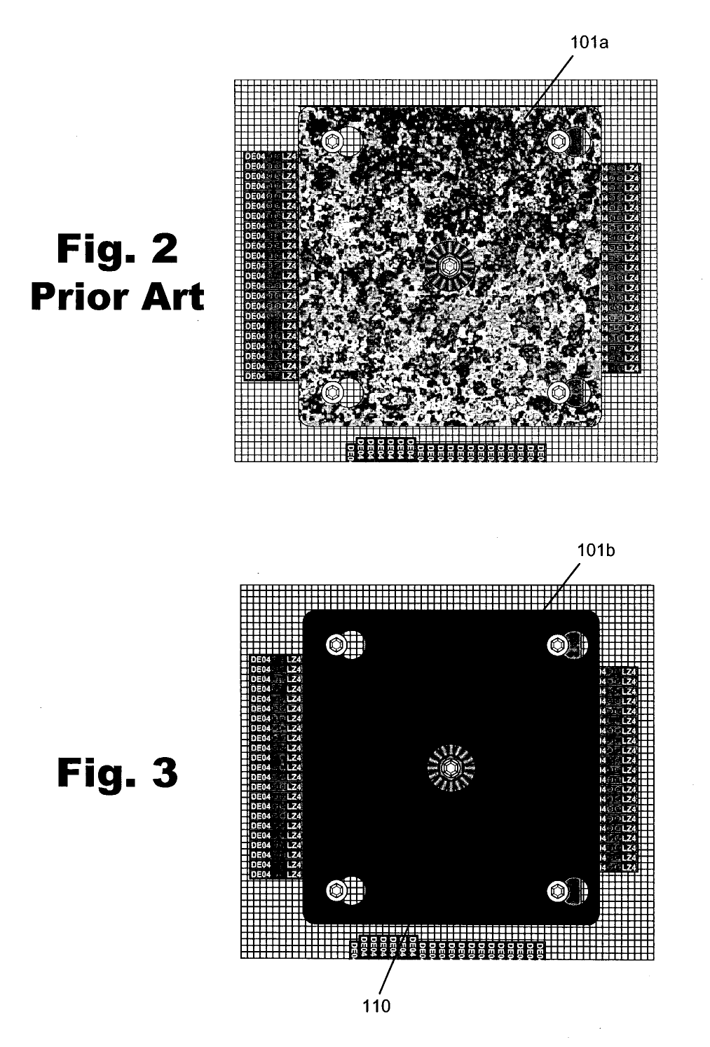

One example of a protective coating is fluoropolymer coating. A fluoropolymer coating has been demonstrated, as will be explained below in connection with FIGS. 2 and 3, to resist and prevent the corrosion of attach hardware under tests conducted by Applicant. On example of a fluoropolymer coating useful for protecting attach hardware components is Xylan® from the Whitford Corporation of Pennsylvania.

FIG. 2 illustrates the corrosion that can occur on a typical load plate (101a) that has no protective coating. The corrosion illustrated on the load plate (101a) in FIG. 2 is the result of a 14-day test in which the unprotected load plate (101a) was exposed to a flow of mixed gasses that would present in the typical operating environment of an ASIC assembly (100, FIG. 1). The flow of the gasses accelerated the corrosion process for purposes of testing the benefit of a protective coating on the load plate as described herein.

In contrast to FIG. 2, FIG. 3 illustrates a load plate (101b) coated with a protective, corrosion-resistant coating (110). The load plate (101b) illustrated in FIG. 3 was coated with Xylan® and subjected to the same 14-day test as the load plate (101a) illustrated in FIG. 2. However, as seen in FIG. 3, the protected load plate (10b) has no visible corrosion and, consequently, significantly enhanced structural integrity.

Obviously, the useful life and reliability of the protected load plate (10b) in FIG. 3 will far exceed those of the unprotected load plate (101a) of FIG. 2. Similar, though perhaps not as dramatic, results can occur when protecting other elements of the attach hardware assembly with a corrosion-resistant coating.

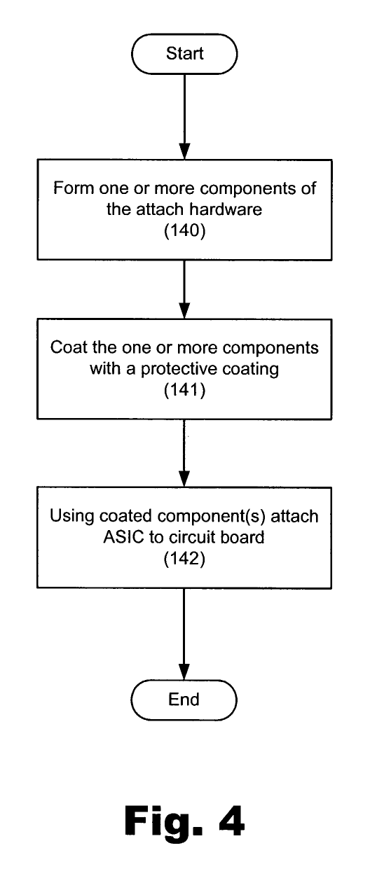

FIG. 4 is a flowchart that illustrates a method of making and using the attach hardware components described herein that are coated with a protective coating. As shown in FIG. 4, the components of the attach hardware assembly, e.g., the load plate (101), the bolster plate (109), the load screw (102) and the load studs (103), are first formed (step 140). In the case of load plate, this may involved casting or cutting a steel plate to the size and shape of the desired load plate.

Next, the component or components of the attach hardware assembly are coated with a protective coating (step 141). In some embodiments, this coating is a fluoropolymer coating. In some embodiments, this fluoropolymer coating is a Xylan® coating. Coating of the components can be coated by, for example, spraying the protective coating on the component.

Lastly, the coated components are used to attach an ASIC to a circuit board to complete the ASIC assembly (step 142). The coated components will then resist corrosion and significantly increase the reliability and useful life of the ASIC assembly (100, FIG. 1).

The preceding description has been presented only to illustrate and describe embodiments of invention. It is not intended to be exhaustive or to limit the invention to any precise form disclosed. Many modifications and variations are possible in light of the above teaching. It is intended that the scope of the invention be defined by the following claims.

What is claimed is:

1. A load plate for attaching an Application Specific Integrated Circuit (ASIC) to a circuit board in an ASIC assembly comprising:
a load plate sized and shaped to apply pressure to an ASIC in an ASIC assembly; and
a protective coating on said load plate to protect said load plate from corrosion.

2. The load plate of claim 1, wherein said load plate comprises steel.

3. The load plate of claim 1, wherein said load plate comprises a hole for receiving a load screw to secure said load plate to said ASIC assembly.

4. The load plate of claim 1, further comprising holes for receiving load studs to connect said load plate to a bolster plate of said ASIC assembly.

5. The load plate of claim 1, wherein said protective coating comprises a flouropolymer coating.

6. The load plate of claim 5, wherein said protective coating comprises Xylan®.

7. An Application Specific Integrated Circuit (ASIC) assembly comprising:
a circuit board;
an ASIC electrically connected to said circuit board; and
an attach hardware assembly for securing said ASIC to said circuit board,
wherein one or more components of said attach hardware assembly are coated with a protective coating to protect that component from corrosion.

8. The assembly of claim 7, wherein said protective coating comprises a flouropolymer coating.

9. The assembly of claim 8, wherein said protective coating comprises Xylan®.

10. The assembly of claim 7, wherein said component with said projective coating is a load plate.

11. The assembly of claim 7, wherein said component with said projective coating is a load screw.

12. The assembly of claim 7, wherein said component with said projective coating is a load stud.

13. The assembly of claim 7, wherein said component with said projective coating is a bolster plate.

14. The assembly of claim 7, further comprising a socket for electrically connecting said ASIC to said circuit board.

15. The assembly of claim 7, further comprising insulation to insulate said ASIC and circuit board from said attach hardware.

16. A component of an attach hardware assembly for securing an Application Specific Integrated Circuit (ASIC) to a circuit board, said component comprising:
said component which is configured to secure an ASIC to a circuit board as part of an attach hardware assembly; and
a protective coating on said component to protect said component from corrosion.

17. The component of claim 16, wherein said component with said projective coating is a load plate.

18. The component of claim 16, wherein said component with said projective coating is a load screw.

19. The component of claim 16, wherein said component with said projective coating is a load stud.

20. The component of claim 16, wherein said component with said projective coating is a bolster plate.

21. The component of claim 16, wherein said protective coating comprises a flouropolymer coating.

22. The component of claim 21, wherein said protective coating comprises Xylan®.

23. A method of protecting a component of an attach hardware assembly for an Application Specific Integrated Circuit (ASIC) assembly from corrosion, said method comprising coating said component with a protective coating to protect said component from corrosion.

24. The method of claim 23, further comprising spraying said coating on said component.

25. The method of claim 23, wherein said component with said projective coating is a load plate.

26. The method of claim 23, wherein said component with said projective coating is a load screw.

27. The method of claim 23, wherein said component with said projective coating is a load stud.

28. The method of claim 23, wherein said component with said projective coating is a bolster plate.

29. The method of claim 23, wherein said protective coating comprises a flouropolymer coating.

30. The method of claim 29, wherein said protective coating comprises Xylan®.

31. A method of producing an Application Specific Integrated Circuit (ASIC) assembly, said method comprising attaching an ASIC to a circuit board using attach hardware, wherein at least one component of said attach hardware is covered with a protective coating to protect said component from corrosion.

32. The method of claim 31, wherein said component with said projective coating is a load plate.

33. The method of claim 31, wherein said component with said projective coating is a load screw.

34. The method of claim 31, wherein said component with said projective coating is a load stud.

35. The method of claim 31, wherein said component with said projective coating is a bolster plate.

36. The method of claim 31, wherein said protective coating comprises a flouropolymer coating.

37. The method of claim 36, wherein said protective coating comprises Xylan®.

38. An Application Specific Integrated Circuit (ASIC) assembly comprising:
a circuit board;
an ASIC electrically connected to said circuit board; and
an attach hardware assembly for securing said ASIC to said circuit board,
wherein one or more components of said attach hardware assembly are provided with a protective means for protecting that component from corrosion.

39. The assembly of claim 38, wherein said protective means comprise a protective coating.

40. The assembly of claim 39, wherein said coating comprises a flouropolymer coating.

41. The assembly of claim 40, wherein said coating comprises Xylan®.

42. The assembly of claim 38, wherein said component with said projective means is a load plate.

43. The assembly of claim 38 wherein said component with said projective means is a load screw.

44. The assembly of claim 38, wherein said component with said projective means is a load stud.

45. The assembly of claim 38, wherein said component with said projective means is a bolster plate.

46. A component of an attach hardware assembly for securing an Application Specific Integrated Circuit (ASIC) to a circuit board, said component comprising:
a component configured to secure an ASIC to a circuit board as part of an attach hardware assembly; and
a protective means on said component for protecting said component from corrosion.

47. The component of claim 46, wherein said component with said projective coating is a load plate.

48. The component of claim 46, wherein said protective means comprise a flouropolymer coating.

49. The component of claim 48, wherein said coating comprises Xylan®.
